(19) United States
(12) Patent Application Publication
(10) Pub. No.: US 2026/0221351 A1
(43) Pub. Date: Jul. 30, 2026

(54) SWITCHING UNIT

(71) Applicant: Ellenberger & Poensgen GmbH, Altdorf (DE)

(72) Inventors: Stefan HOLBE, Nuernberg (DE); Hendrik-Christian KOEPF, Nuernberg (DE); Julian KAISER, Erlangen (DE)

(73) Assignee: Ellenberger & Poensgen GmbH, Altdorf (DE)

(21) Appl. No.: 19/460,906

(22) Filed: Jan. 27, 2026

(30) Foreign Application Priority Data
Jan. 27, 2025 (DE) 10 2025 102 792.7

(51) Int. Cl. H01H 1/06; H02G 5/02; H05K 1/181

(52) U.S. Cl. CPC H01H 1/06; H02G 5/02; H05K 1/181; H05K 2201/10053

(57) ABSTRACT

A switching device having a mechanical switch having a first busbar. A first fixed contact and a second busbar have a first moving contact, which is assigned to the first fixed contact. The switching device also comprises a printed circuit board on which the first busbar is mounted.

This nonprovisional application claims priority under 35 U.S.C. § 119(a) to German Patent Application No. 10 2025 102 792.7, which was filed in Germany on January 27, 2025, and which is herein incorporated by reference.

### BACKGROUND OF THE INVENTION

### Field of the Invention

The invention relates to a switching device. The switching device has a mechanical switch comprising a first busbar with a first fixed contact and a second busbar with a first moving contact.

### Description of the Background Art

Usually, circuit breakers are used to protect an electrical line or device against a malfunction of the associated circuit, such as an excessive electrical voltage or an excessive flowing electric current. This occurs, for example, in the event of previous damage to the device to be protected or the electrical cable. In this case, the current flow is interrupted by means of the circuit breaker, so that further damage is avoided.

To interrupt the current flow, the circuit breaker has a switch. Thus, the circuit breaker represents a formation of a switching device. To provide contact protection and easy installation, the switch is arranged within a housing. For example, the switch is designed as a semiconductor switch. Due to its design, this has an internal resistance, which is why it is heated during operation, at least when a comparatively large electric current is conducted. Cooling is therefore required. Efficiency is also reduced. In an alternative, the switch is mechanically designed and in active connection with a drive that includes an electromagnet, for example. By energizing the drive, it is thus possible to change the switching state of the switch.

To conduct the electrical current to be switched, the mechanical switch usually comprises several busbars, which are generally arranged in a respective receptacle of a housing that is designed as a plastic injection molded part. Thus, the busbars are suitably stabilized, wherein one of which is assigned a fixed contact. An additional busbar is assigned a moving contact, and this is movably mounted, especially by means of the drive. By operating the drive, it is possible to mechanically apply the moving contact to the fixed contact or to distance these from each other. The drive, in turn, is operated by means of a control unit, to which a printed circuit board is assigned, and by means of which any sensors or the like are also read, depending on which the drive is actuated. The power supply of the control unit is usually independent of the circuit that is switched by means of the mechanical switch. Therefore, the mechanical switch is usually spaced apart from the PCB, which reduces the requirements for electrical insulation.

If the semiconductor switch is used as a switch, it is usually attached directly to the PCB and electrically contacted with several conductor tracks of the PCB. Since comparatively high electrical currents are carried by means of the semiconductor switch, it is necessary that the conductor tracks have a comparatively large thickness. This leads to increased manufacturing costs for the PCB.

### SUMMARY OF THE INVENTION

It is therefore an object of the present invention to provide a suitable switching device, wherein manufacturing costs are advantageously reduced, and wherein, expediently, production is simplified and/or robustness is increased.

The switching device is used in particular to switch an electric current, i.e., in particular to create and/or interrupt an electrical current flow. For this purpose, the switching device has two states, namely an electrically conductive state, which is also referred to as a closed state. In this case, it is possible to conduct the electric current by means of the switching device. In the other state, which is referred to as an open or electrically non-conductive state, an electric current flow via the switching device is not possible. For example, the switching device is manually actuated/actuatable, so the switching device is a manual switch. Alternatively or in combination with this, it is possible, for example, to actuate the switching device electrically and thus especially remotely. In another alternative, for example, the switching device is automatically actuated, depending on certain conditions. Appropriately, the switching device is a circuit breaker or a contactor.

For example, the circuit breaker is used to protect a device, and the circuit breaker is a device circuit breaker, for example. Alternatively or in combination with this, the circuit breaker serves to protect a line and is therefore a line circuit breaker. In particular, the circuit breaker is used in a DC circuit, for example between a load and a DC link or the like, so that a circuit is formed in particular. Preferably, there is an electrical DC voltage between 400 V and 650 V in the DC circuit, i.e., in particular a higher DC voltage. Preferably, the circuit breaker is used to protect an actuator in an industrial plant. The actuator forms the load in particular. The circuit breaker is expediently used in the field of industrial automation. In particular, the electrical voltage switched by means of the circuit breaker is 24 V, 48 V, 380 V, 650 V, 760 V. In an alternative, the circuit breaker is used to protect street lighting, a ship's electrical system, railway applications-infrastructure, railway applications-propulsion or in the field of electrified aviation. In another alternative, the circuit breaker is used in the expansion and integration of renewable energy generators, in island grids, in the private domestic sector, in greenhouses, in the electrification of road-based mobility (electromobility), agriculture or in construction site vehicles. The electrical (direct) voltage used is, for example, between 1500 V and 3000 V or is 110 V, 380 V, 400 V 800 V, 1000 V 1500 V, 3000 V. In summary, as an alternative to the application in an industrial plant, the circuit breaker is used, for example, in an electric vehicle, such as a motor vehicle, an airplane or a ship/boat.

The switching device can be designed as an isolating switch, which is also known as a disconnector. For example, the switching device includes a mechanical lever that can be used to change the switching state of the control unit.

In particular, the switching device comprises two terminals between which a current path is conveniently formed and to which other components of the circuit are connected when installed. The terminals are suitable for this purpose, in particular provided and set up. Expediently, a cable or a busbar is connected to the respective terminal, with a cross-section of this being between 10 mm2 and 100 mm2 or between 25 mm2 and 92 mm2, for example. For example, the cross-section is 16 mm2, 25 mm2 or 35 mm2. For example, the cross-section is 6 mm2, between 6 mm2 and 16 mm2 or between 16 mm2 and 50 mm2. In particular, the terminals are designed in the manner of cage clamps or at least include them.

The switching device can have a mechanical switch. In this case, the mechanical switch is conveniently assigned to the possible current path, i.e., in particular electrically connected between the two terminals of the switching device. This makes it possible to switch the electrical current flow via the switching device by means of the mechanical switch. The mechanical switch is suitably arranged in a housing, preferably made of a plastic. This provides contact protection for the mechanical switch, which is also protected from environmental influences. Conveniently, the possible terminals are inserted into the housing, so that electrical contact of the possible current path or at least of the mechanical switch is possible from outside the housing.

The switching device can have a first busbar and a second busbar. The first busbar comprises a first fixed contact and the second busbar a first moving contact. The first moving contact is associated with the first fixed contact. In particular, the second busbar is movably mounted, and it is possible to mechanically attach the first moving contact to the first fixed contact and also to distance them from each other. In the case of the mechanically direct attachment of the first moving contact to the first fixed contact, an electric current flow via the mechanical switch is possible, and in particular therefore also via the switching device. If, on the other hand, the first moving contact is separated from the first fixed contact, an electric current flow is not possible, and it is then convenient for the two possible terminals to be galvanically isolated from each other. At a minimum, the current path is preferably separated. At the very least, however, there is no electrical current flow via the mechanical switch.

The first fixed contact, for example, can be attached to the other components of the first busbar and is therefore electrically contacted. For example, the first fixed contact is one-piece with and/or molded to the other components of the first busbar. Alternatively, the first fixed contact is made of a different material, such as a body of the first busbar. This makes it possible to increase burn resistance there. Conveniently, the first fixed contact is riveted, soldered or welded to the body of the first busbar. Conveniently, the first busbar, especially with the exception of the first fixed contact or at least the body, is made of copper, preferably nickel-plated copper.

The first moving contact can be in particular molded to a body of the second busbar or preferably attached there and also electrically contacted. For example, this is also done by riveting, soldering or welding. Appropriately, the bodies of the first and second busbars are made of the same material. Conveniently, the first fixed contact is made of the same material as the first moving contact. This means that they can each be manufactured from the same semi-finished product, which simplifies warehousing.

The switching device also can have a printed circuit board, which suitably comprises a body made of a glass fiber reinforced epoxy resin. In particular, the printed circuit board comprises several conductor tracks that are attached to and/or embedded in the body made of glass fiber reinforced epoxy resin. The conductor tracks are conveniently made of copper. The first busbar is mounted on the PCB. In other words, the first busbar is not originally a component of the PCB and is therefore not created by etching, milling or other abrasive processes, i.e., by removing components of the PCB. Rather, the arrangement of the first busbar on the PCB is done by means of an additive process, so that the first busbar is added to the already finished PCB.

For example, the first busbar can be attached to the PCB by means of surface mounting, and the first busbar is, in particular, designed as an SMD component. For this purpose, the first busbar has suitable pads. In an alternative, for example, the first busbar is mounted on the PCB by means of through-hole mounting. For this purpose, the first busbar has suitable legs or wire-like appendages that are inserted into corresponding holes in the circuit board. In particular, the first busbar is soldered and/or glued to the PCB for assembly. In another alternative, the first busbar is attached to the PCB using press-fit methods/press-fit technology.

Due to such a design, the electrical current conducted via the mechanical switch is not carried through the printed circuit board, so that it is not necessary to excessively increase the current-carrying capacity of the printed circuit board. This reduces manufacturing costs. The first busbar is stabilized by means of the printed circuit board, which increases robustness. It is also possible to mount the first busbar on the PCB, for example, in a single step with the assembly of other components, such as electrical and/or electronic components, on the PCB, so that work steps can be saved. Mechanized production is also possible, which further reduces manufacturing costs.

For example, the first busbar can be electrically isolated from other components of the PCB. This increases safety. Alternatively, for example, other components of the switching device are electrically contacted to the first busbar by means of any conductor tracks of the printed circuit board. In particular, this makes it possible to measure or determine the electrical current carried by the first busbar.

For example, the first busbar can be arranged parallel to the PCB and rests flat on it, for example. Thus, stability is increased. Alternatively, a body of the first busbar is spaced apart from the PCB and is held there, for example, by means of corresponding angled holders of the first busbar, which are attached to the PCB. This avoids an electrical short circuit with other components attached to the PCB. In this way, a comparatively large amount of installation space is also available for the assembly of any electrical and/or electronic components. Particularly preferred, the first busbar is arranged perpendicular to the PCB. In other words, the printed circuit board is, in particular, arranged in a plane and the first busbar, in particular the possible body of the busbar, is arranged perpendicular to it. Preferably, the first busbar is essentially strip-shaped, and thus predominantly has an expansion in one plane. This plane is arranged perpendicular to the printed circuit board. Appropriately, the course of the first busbar, i.e., its longitudinal direction, at least in the area of the first fixed contact, is parallel to the printed circuit board. On the one hand, this reduces the material requirement of the first busbar. On the other hand, this means that a comparatively large amount of installation space is available for the PCB to be able to arrange any electrical and/or electronic components. Suitably, the first busbar rests at the edge of the circuit board. This increases robustness.

For example, the second busbar can be mounted on a swivel bearing. However, particularly preferred, the second busbar is mounted perpendicular to its longitudinal direction and/or the longitudinal direction of the first busbar. Thus, construction is simplified. Appropriately, the mechanical switch includes a third busbar with a second fixed contact, and the second busbar includes a second moving contact. Here, the second moving contact is assigned to the second fixed contact. Thus, especially when the second busbar is moved, the second moving contact is moved away from the second fixed contact, and the first moving contact is moved away from the first fixed contact or mechanically brought into contact with each other. In particular, the mechanical switch is therefore designed in the manner of a double breaker, which is why the electrical voltage applied between each fixed contact and the assigned moving contact is reduced in the open switching state of the mechanical switch. As a result, the formation of an electric arc is prevented there, or this only occurs when the electrical voltage is comparatively high. It is expedient to assign a quenching chamber to each fixed contact and the assigned moving contact. If only the first fixed contact and the first moving contact are present, the quenching chamber is also preferably assigned to them. In particular, the quenching chamber is used to extinguish the respective arc. For this purpose, the quenching chamber conveniently comprises several quenching plates or the like.

In particular, all busbars can be essentially arranged perpendicular to the printed circuit board, wherein their course, i.e., in particular the direction in which they have the greatest expansion, is parallel to the printed circuit board. Thus, the busbars are stabilized by means of the printed circuit board, wherein the size required is reduced.

For example, in order to distance the moving contacts from the respective assigned fixed contact, the second busbar is tilted, swiveled or, in particular, moved transversely. For example, some of the busbars are arranged vertically or transversely to each other. However, all busbars are particularly preferred to be parallel to each other. This simplifies construction and reduces the need for space. Particularly preferably, the first busbar and the third busbar are located in a common plane, preferably perpendicular to the PCB. This further simplifies the design. The mechanical switch is particularly preferably designed to be essentially symmetrical. Consequently, the design is further simplified, and in particular, the number of different components is reduced.

For example, the mechanical switch can only be operated manually. However, it is particularly preferable to have a drive by means of which the second busbar is driven. Thus, it is possible to change the switching state of the mechanical switch by actuating the drive. For example, it is only possible to change the switching state of the mechanical switch in one direction, for example only from the electrically conductive to the electrically non-conductive state, or vice versa. Consequently, the design is simplified. However, particularly preferably, it is possible to use the drive to change the switching state of the mechanical switch in both directions, i.e., to set it to both the electrically conductive and the electrically non-conductive state. Thus, functionality is increased. For example, the drive is mechanically designed. However, the drive is particularly preferred to be electric. For example, the combination of the mechanical switch and the drive forms a relay. Conveniently, the drive includes an electric coil. When the drive is in operation, a magnetic component, such as a permanent magnet or a ferromagnetic component, is appropriately moved within the coil.

The drive can be designed as a "moving magnet actuator", for example. The " moving magnet actuator " is also assigned to the magnetic component that is movably mounted. In addition, the "moving magnet actuator" has a drive unit with one or more electric coils that are energized when the drive is actuated, so that a magnetic interaction takes place between them and the component. The electrical coils are kept stationary. Since the electrical coil(s) is/are stationary, the design is simplified and, with the exception of the components required for bearing, no other movable components or electrical connections are required between the moving components, namely the component and the stationary components of the "moving magnet actuator ", which is hereinafter referred to simply as the actuator. This also reduces friction.

Preferably, the drive unit comprises two electric coils, which are identical in construction, for example. At the very least, however, the two electric coils are offset from each other along a longitudinal axis and arranged concentrically to it. The component is located in particular on the longitudinal axis and is movably supported along it. When the mechanical switch is in the switching state, the component is located in an air gap between the two electrical coils and is held there, for example, by means of a magnetic short-circuit plate. In the other switching state, however, the component is offset along the longitudinal axis.

Since the number of moving components of the "moving magnet actuator ", in particular only the component, is comparatively small, and these in particular have a comparatively low weight, the dynamics of the actuator are comparatively high. This reduces inertia when actuating the mechanical switch. As a result, the switching device enables comparatively fast switching.

Preferably, the drive is used to support the second busbar. This reduces the number of components required. For example, the drive is separate from the PCB. This allows for a flexible design. It is also possible to design the switching device modularly, which is why versatility is improved. However, the drive is particularly preferred to be connected to the printed circuit board. Thus, the drive is also stabilized by means of the PCB, which increases robustness. In this way, a comparatively precise alignment of the second busbar with respect to the first busbar is also achieved, which is why the switching behavior of the mechanical switch is improved. Advantageously, in this case the drive is electrically designed, and preferably the individual components of the drive, or at least some of them, are interconnected by means of the printed circuit board. This further reduces the number of components required and manufacturing costs.

Preferably, the switching device includes a control unit by means of which the drive is operated. In this case, the control unit is conveniently provided by means of the printed circuit board. In other words, the printed circuit board comprises several electrical and/or electronic components that are interconnected by means of some of the conductor tracks of the printed circuit board. Thus, a circuit is provided, by means of which the control unit in particular is formed. As a result, the control unit is also stabilized in terms of the drive, which is why robustness is further improved. It is also possible, for example, to mount the individual components of the control unit and/or the drive and the first busbar on the PCB in a single step. Consequently, manufacturing time is further shortened.

Conveniently, the switching device includes several sensors, which are read out by means of the control unit, for example. The sensors are also conveniently attached to the circuit board and electrically connected to the control unit via some of the conductor tracks of the circuit board, thus providing a signal connection. This makes it even easier to manufacture and further increases robustness. Preferably, at least one of the sensors is assigned to the first and/or the third busbar. Thus, in particular, an electrical voltage and/or a respective electric current carried between them can be detected. Preferably, depending on this, the drive is operated by means of the control unit, and the switching device in this case is preferably designed as a circuit breaker.

In particular, the switching device includes an interface that is connected to the control unit, for example. Depending on an electrical voltage applied to the interface and/or data received via said interface, the drive is preferably operated. The interface is preferably soldered to the PCB. As a result, a number of components required is also reduced here, and the manufacturing process can, for example, essentially only be automated.

For example, one of the busbars protrudes over the PCB. However, it is particularly preferable that all busbars are covered by the printed circuit board. In other words, in the expansion plane of the PCB, none of the busbars protrude over the edge of the PCB. This prevents an electrical short circuit there, and the busbars are kept comparatively stable by means of the circuit board. In summary, the PCB has a greater expansion than the busbars, and/or the busbars are suitably shaped/curved.

For example, the second busbar rests on the PCB and is routed along and/or by means of it, for example. This means that the second busbar is arranged comparatively stably, although friction in particular is increased. Therefore, the second busbar is preferably spaced apart from the PCB. Thus, the switching speed of the mechanical switch is increased due to the reduced friction. For example, the course of the second busbar is essentially perpendicular to the course of the first busbar and/or to the PCB.

Conveniently, however, the course of the second busbar is essentially parallel to the plane of the PCB and/or the first busbar. In particular, the first busbar has an extension to which the first fixed contact is assigned. In other words, the first fixed contact is located at the extension, and by means of this it is spaced from the PCB. Consequently, it is possible to stabilize the first busbar by means of the printed circuit board, without hindering the movement of the second busbar by means of the printed circuit board. For example, the first busbar is essentially L-shaped, wherein one of the legs conveniently rests against the PCB at the edge. The other leg preferably runs perpendicular to the printed circuit board, and the first fixed contact is arranged here, conveniently on the end side. However, the first busbar is essentially U-shaped. In other words, there is also another leg that is spaced apart from the PCB and runs parallel to the PCB. For example, this is freely oscillating or held at the end side. Due to the U-shape, stability is increased. In addition, just as with the L-shaped design of the first busbar, there is a concentration of the magnetic field due to the Lorentz force when an electric current flows that is counter to the magnetic field provided by the second busbar. As a result, the two busbars repel each other, which is why an opening movement of the mechanical switch is accelerated without having to apply a comparatively high force by means of the possible drive. Rather, it is only necessary, for example, to hold the two busbars so that the first moving contact is held to the first fixed contact, at least as long as the electrical current flow is to exist via the switching device.

For example, the switching device is only mechanically designed. Alternatively, the switching device also includes a semiconductor switch, which is a field-effect transistor, for example. Specifically, the semiconductor switch is a power semiconductor switch, such as a MOSFET, JFET, GTO, or IGBT. For example, the semiconductor switch is spaced apart from the PCB. The semiconductor switch is particularly preferred to be mounted on the printed circuit board and thus electrically contacted and attached to it. At the same time, mechanized production of the switching device is still possible, at least in part. It is also possible to mount the semiconductor switch in a single step when assembling, for example, the possible control unit or the first busbar on the printed circuit board. Preferably, the semiconductor switch is attached to the PCB by means of a surface mount. This stabilizes the semiconductor switch and reduces the number of components required. In particular, the PCB includes a driver circuit, or at least it is mounted on the PCB or appropriately provided by means of it. This enables the semiconductor switch to be operated by means of the printed circuit board, which is why the number of components required is further reduced.

Conveniently, another busbar is mounted on the circuit board, which is electrically routed against one of the possible connections. The additional busbar is also separated from the first busbar. In particular, these are separate from each other. This avoids an electrical short circuit between the first busbar and the additional busbar. Advantageously, the additional busbar and the first busbar are electrically contacted to each other by means of the semiconductor switch. Thus, it is possible to interrupt or create an electrical current flow between the additional busbar and the first busbar by means of the semiconductor switch. Due to the two busbars, a high electric current is only conducted to the semiconductor switch via the PCB over a comparatively short section, which reduces the demands on the PCB.

For example, the semiconductor switch is electrically connected parallel to the mechanical switch. In this case, the other busbar is electrically contacted with the second busbar at low impedance, for example via the possible conductor tracks of the circuit board, or directly. Alternatively, for example, another additional busbar is used, which is electrically contacted with the second busbar and the other busbar. In another further development, the other busbar is molded to the second busbar. It is particularly preferable that before the mechanical switch is opened, the semiconductor switch is set to the electrically conductive state. When the first moving contact is separated from the first fixed contact, the electric current commutates to the semiconductor switch, so that, for example, no arc forms between the first moving contact and the first fixed contact. If these are far enough apart from each other, it is expedient to set the semiconductor switch to the electrically non-conductive state. This prevents the flow of electrical current via the switching device. Due to the mechanical switch, there is only low electrical resistance in normal operation, especially as compared to the use of only the semiconductor switch, which improves efficiency. Conveniently, the additional busbar and the first busbar can be arranged parallel to each other and along a longitudinal direction. In this case, the additional busbar and the first busbar are spaced apart from each other, and an overlap is formed between them perpendicular to the longitudinal direction. The overlap is located in the longitudinal direction between the terminal and the first fixed contact. The semiconductor switch and the other semiconductor switch(es), preferably all existing semiconductor switches, are electrically contacted in the area of the overlap with the additional busbar and the first busbar. In particular, the semiconductor switches are connected in parallel to each other. Preferably, there are the strings that are electrically connected in parallel to each other and electrically contacted in the area of the overlap with the additional busbar and the first busbar. As a result, the length of the path for the electric current between the terminal and the first fixed contact is always the same, regardless of which semiconductor switch the electric current passes through. As a result, the load is distributed across the semiconductor switches/strings, thus avoiding overloading. In summary, the semiconductor switches/strings are arranged symmetrically, in particular.

The semiconductor switch can also be conveniently connected electrically in series to the mechanical switch. Thus, the semiconductor switch is electrically located between the second busbar and the other busbar. In this way, it is possible, for example, to first interrupt the electrical current via the switching device by means of the semiconductor switch, and then to set the mechanical switch to the open state. Here, too, there is no arc, although the possible connections are galvanically isolated from each other due to the mechanical switch.

In particular, the other busbar can be routed against one of the terminals and preferably electrically contacted with it. Thus, from the terminal to the other busbar / semiconductor switch, the electrical current is not conducted by means of the printed circuit board or any other component, which makes assembly and production easier. The number of required components is also reduced.

For example, only the sole semiconductor switch is available. For example, the semiconductor switch is guided directly against the busbar and the additional busbar. Alternatively, for example, there is another semiconductor switch, and these are electrically connected in series, namely between the additional busbar and the first busbar. Thus, the electrical voltage switched by each of the semiconductor switches is reduced, which reduces the requirements for them. Alternatively, these are antiparallel to each other, for example. As a result, it is possible to operate the switching device bidirectionally. In another alternative, the two semiconductor switches are electrically connected in series to each other. Thus, the electrical current flow via the switching device is distributed to the individual semiconductor switches, which reduces the requirements for them. This reduces manufacturing costs.

Preferably, there are several semiconductor switches, wherein several strings are formed, which are expediently identical in construction to each other. Each string has several of the semiconductor switches, which are electrically connected in series. The strings, in turn, are electrically connected in parallel between the first and the additional busbar. This results in a distribution of the electric current among the different strings, wherein the electrical voltage switched by means of each of the semiconductor switches is reduced. This further reduces the requirements for the semiconductor switches.

If the other semiconductor switch(es) are present, they are conveniently operated at the same time as the semiconductor switch. Preferably, all semiconductor switches are identical to each other, which simplifies warehousing.

For example, the semiconductor switches can be different from each other or preferably identical in construction to each other. Thus, identical parts can be used. It also ensures that the electrical current is distributed essentially evenly among the semiconductor switches, as they have the same electrical properties.

The switching device can be used for DC voltage and/or DC current interruption. Appropriately, the switching device is used in a motor vehicle or an industrial plant. The invention also relates to the corresponding use of the switching device, which is preferably a circuit breaker. The invention also relates to an electrical circuit which has such a switching device. In this case, the circuit conveniently includes a DC voltage source and a load. In particular, the electrical circuit is a component of a motor vehicle. For example, the DC voltage source is an energy storage device, such as a high-voltage battery, and the load is, for example, an electric motor or at least a drive that includes the electric motor. In this case, the load can also act as a source, namely in a regenerative operation of the electric motor, which leads to the motor vehicle decelerating. In the circuit, for example, the current direction is bidirectional.

The switching device can be conveniently designed as a circuit breaker. In this case, the mechanical switch is appropriately operated depending on a tripping characteristic. Preferably, the mechanical switch is opened by means of the drive if an electric current has been carried for a certain period of time, which is specified by the tripping characteristic. It is convenient to have the control unit and/or a sensor to detect the electrical current carried by the circuit breaker. The sensor preferably includes a shunt. The invention also relates to such a circuit breaker.

The further developments and advantages explained in connection with the switching device are also to be transferred mutatis mutandis to the use / circuit / circuit breaker as well as to each other, and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows schematically, a DC circuit with a load and a circuit breaker,

FIG. 2 is the circuit breaker in perspective, which comprises a housing with two housing halves, and

FIG. 3 is the circuit breaker in perspective, with one of the housing halves removed.

### DETAILED DESCRIPTION

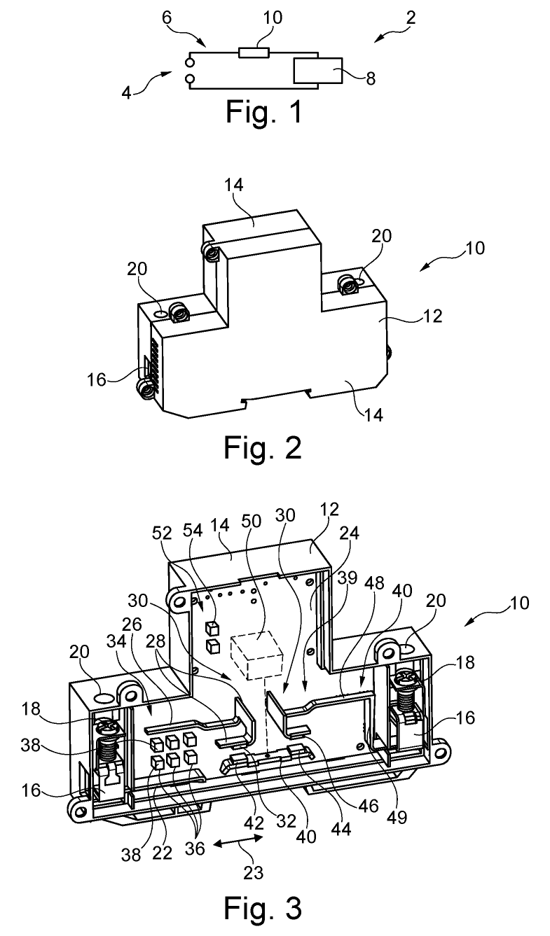

FIG. 1 schematically simplifies a DC circuit 2, which comprises a DC voltage source 4. By means of this, an electrical DC voltage of 650 V is provided, and by means

of this a DC link 6 is powered. By means of this, a load 8 is supplied, which is electrically connected to the DC link 6 via a switching device 10. It is possible, for example, that in certain states the load 8 acts as the source. Thus, the DC circuit 2 is bidirectional.

FIG. 2 shows the switching device 10 in perspective, which is designed as a circuit breaker. The switching device 10 has a housing 12 with two housing halves 14, which are joined together and made of a single plastic. FIG. 3 shows the switching device 10 in perspective, with one of the two halves of the housing 14 removed. Two openings are inserted into the housing 12, within each of which a terminal 16 is arranged. There, it is possible to connect a line of the DC link 6 or an electrical line assigned to the load 8. The terminals 16 each have a clamping screw 18, which is accessible through a mounting hole 20 of the housing 12. By screwing in the clamping screws 18, the line assigned to the respective terminal 16 is clamped and thus electrically contacted.

One of the terminals 16 is electrically contacted with another busbar 22, which is made of tinned copper. The additional busbar 22 is strip-shaped and essentially arranged in one plane only. In this case, a longitudinal direction 23 of the additional busbar 2 located in the plane is directed from the assigned terminal 16 to the remaining terminal 16, from which the additional busbar 22 is spaced.

The additional busbar 22 is arranged perpendicular to a PCB 24 and rests on the edge of it. Thus, the plane in which the additional busbar 2 is located runs perpendicular to the plane in which the PCB 24 is located, wherein the longitudinal direction 23 is parallel to the PCB 24. The additional busbar 22 is also mounted on the PCB 24, namely by means of through-hole mounting. For this purpose, the edge of the additional busbar 22 has several unspecified wire-like extensions, which are plugged through the PCB 24 and soldered to it.

Parallel to the additional busbar 22, but offset laterally with respect to it, a first busbar 26 is mounted on the circuit board 24. The first busbar 26 also rests on the edge of the circuit board 24 and has corresponding wire-like extensions, which are led through suitable openings of the circuit board 24 and soldered there. Thus, the first busbar 26 is also arranged perpendicular to the PCB 24 and is mainly oriented in the longitudinal direction 23. In summary, the additional busbar 22 is routed against one of the terminals 16 and is spaced apart from the first busbar 26.

The shape of the first busbar 26 is essentially U-shaped, so that, in addition to the part of the first busbar 26 adjacent to the PCB 24, there are two legs 28 by means of which an extension 30 is formed, which is spaced from PCB 24. One of the legs 28 is arranged parallel to the longitudinal direction 23 and the other is perpendicular to it. A first fixed contact 32 of the first busbar 26 is assigned to the extension 30, which is made of a different material than the extension 30 and welded to it. The first fixed contact 32 is spaced apart from the PCB 24 due to the extension 30.

In the longitudinal direction 32, an overlap 34 is formed between the fixed contact 32 and the terminal 16, against which the additional busbar 20 is guided. In other words, the first busbar 26 and the additional busbar 22 overlap at their ends in the longitudinal direction 23. In the area of the overlap 34, the additional busbar 22 and the first busbar 26 are electrically contacted by means of several strings 36, which are electrically connected in parallel. Each of the strings 36 comprises two semiconductor switches 38 that are electrically connected in series. The semiconductor switches 38 are identical in construction and designed as MOSFETs. The semiconductor switches 38 are also mounted on the PCB 24, namely by means of surface mounting. In other words, the semiconductor switches 38 are SMD components.

In summary, the additional busbar 22 and the first busbar 26 are arranged parallel to each other and along the longitudinal direction 23 in such a way that the overlap 34 is formed in the longitudinal direction 23 between the assigned terminal 16 and the first fixed contact 32. The semiconductor switches 38 in the area of overlap 34 are electrically contacted with the additional busbar 22 and the first busbar 26. Due to such an arrangement, the length between the terminal 16 and the fixed contact 32 for the electric current is always the same, regardless of which of the strings 36 the electric current has flowed through.

The first busbar 26, which comprises the first fixed contact 32, is a component of a mechanical switch 39, which also has a second busbar 40 with a first moving contact 42 and a second moving contact 44. The second busbar 14 also extends longitudinally 23 but is spaced from the PCB 24. The first moving contact 42 is assigned to the first fixed contact 32, and the second moving contact 44 is assigned to a second fixed contact 46 of a third busbar 48 of the mechanical switch 39, which is essentially axially symmetrical to the first busbar 26 and arranged accordingly. Thus, the third busbar 48 also has the extension 30, to which the second fixed contact 46 is assigned, which is spaced from the PCB 24. With the exception of the extension 30, the third busbar 48 is also connected to the edge of the PCB 24 and is mounted on it. Also, the third busbar 48 is arranged in the same plane as the first busbar 26. Consequently, the first busbar 26, the second busbar 40 and the third busbar 48 are arranged essentially parallel to each other.

In this case, all busbars 26, 40, 48 of the mechanical switch 39 are spaced apart from the edge of the PCB 24, which is why they are covered by the PCB 24. In other words, none of these busbars 26, 40, 48 protrudes over the PCB 24, so that an electrical short circuit is avoided.

At the end of the third busbar 48 opposite the extension 30, an additional busbar 49 is formed, which runs perpendicular to the longitudinal direction 23 and is guided against the remaining terminal 16. Thus, the two terminals 16 are electrically connected to each other by means of the additional busbar 49, the mechanical switch 39, the strings 36 and the additional busbar 22.

The second busbar 40 is driven by a drive 50 and is mounted perpendicular to the longitudinal direction 23 and parallel to the PCB 24. Thus, it is possible to move the second busbar 40 perpendicular to the longitudinal direction 23 and parallel to the PCB 24 by means of the drive 50. Here it is possible to bring the first moving contact 42 into mechanical direct contact with the first fixed contact 32, wherein the second moving contact 44 is then also in contact with the second fixed contact 46. If the semiconductor switches 38 are then electrically conductive, an electrical current flow between the terminals 16 is possible. It is also possible to move the second busbar 40 by means of the drive 50 in such a way that the moving contacts 42, 44 are separated from the fixed contacts 32, 46. Consequently, an electrical current flow between the terminals 16 is prevented, even if the semiconductor switches 38 are electrically conductive.

The drive 50 is connected to the PCB 24 and thus stabilized. Consequently, no alignment of the second busbar 40 is necessary, since its position is determined by the mounting position of the drive 50 and thus by means of the PCB 24, which is also used to specify the position of the first and third busbars 26, 48. The drive 50 is operated by means of a control unit 52, which has several electrical and/or electronic components 54. In this case, the semiconductor switches 38 are also operated by means of the control unit 52, i.e., they are set to the electrically conductive or electrically non-conductive state. The components 54 are connected to each other by means of unspecified conductor tracks of the circuit board 24, so that the control unit 52 is provided by means of the circuit board 24, by means of which the drive 50 is operated, by means of which the second busbar 40 is driven in turn. The electrical contacting of the drive 50 with the control unit 52 is carried out by means of the conductor tracks of the PCB 24, which is why no separate cabling is required, which simplifies assembly.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A switching device comprising:
a mechanical switch comprising a first busbar with a first fixed contact and with a second busbar having a first moving contact assigned to the first fixed contact; and
a PCB to which the first busbar is mounted.

2. The switching device according to claim 1, wherein the first busbar is arranged substantially perpendicular to the PCB.

3. The switching device according to claim 1, wherein the mechanical switch has a third busbar with a second fixed contact, and wherein the second busbar comprises a second moving contact which is assigned to the second fixed contact.

4. The switching device according to claim 3, wherein all busbars are substantially parallel to each other.

5. The switching device according to claim 1, wherein a drive is connected to the printed circuit board via which the second busbar is driven.

6. The switching device according to claim 5, wherein a control unit is provided via the printed circuit board via which the drive is operated.

7. The switching device according to claim 1, wherein all busbars are covered by the PCB.

8. The switching device according to claim 1, wherein the first busbar has an extension to which the first fixed contact is assigned, and wherein the first fixed contact and the second busbar are spaced apart from the PCB.

9. The switching device according to claim 1, wherein an additional busbar is mounted on the PCB, which is electrically routed against a terminal and is spaced apart from the first busbar, and wherein the additional busbar and the first busbar are electrically contacted to each other via a semiconductor switch mounted on the PCB.

10. The switching device according to claim 9, wherein the additional busbar and the first busbar are arranged parallel to each other and along a longitudinal direction such that an overlap is formed in the longitudinal direction between the terminal and the first fixed contact, and wherein the semiconductor switch and a further semiconductor switch are electrically contacted in the area of the overlap with the additional busbar and the first busbar.
